(19) United States
(12) Patent Application Publication
(10) Pub. No.: US 2010/0072609 A1
(43) Pub. Date: Mar. 25, 2010

(54) Socket for semiconductor integrated circuit

(75) Inventor: Toshiki Fukumoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,595

(22) Filed: Nov. 24, 2009

(30) Foreign Application Priority Data
Jan. 12, 2008 (JP) 306293/2008

(51) Int. Cl. H01L 23/04

(52) U.S. Cl. 257/698

(57) ABSTRACT

Provided is a socket for semiconductor integrated circuit allowing a semiconductor integrated circuit to be analyzed easily. The socket for semiconductor integrated circuit according to the invention is used by mounting a package thereon. The socket for semiconductor integrated circuit includes: a socket main body which covers both a front-side surface and a back-side surface of the package and is provided with a window formed above either of the two surfaces of the package; bottom-side socket pins provided corresponding respectively to package balls of the package; upper-side socket pins provided corresponding respectively to the package balls of the package at the time when the package is mounted upside down; and wirings which electrically connect the bottom-side socket pins to the corresponding upper-side socket pins, respectively.

### BACKGROUND OF THE INVENTION

1. Field of the Invention The invention relates to a socket for semiconductor integrated circuit.

2. Description of the Related Art

A socket for semiconductor integrated circuit is used to conduct an electrical test on a semiconductor integrated circuit, such as a bare chip and a packaged chip. Japanese Patent Application Publication No. 62-110282 (JP-A 62-110282), for example, discloses a technique related to sockets for semiconductor integrated circuit. The socket for semiconductor integrated circuit of JP-A 62-110282 includes a socket main body provided with a hollow space for mounting a semiconductor integrated circuit upside down. Pin insertion holes are formed in an interior upper wall of the socket main body. In the inside of the socket main body, pins of a semiconductor integrated circuit are inserted into the pin insertion holes. In this way, the semiconductor integrated circuit is mounted on the socket for semiconductor integrated circuit. A window is formed at the center in the upper-side portion of the socket main body. To observe the operation state of the semiconductor integrated circuit by use of an IC tester, probes are brought into contact with the chip surface through the window. The window also allows an electron beam to be used for failure analysis of the semiconductor integrated circuit.

### SUMMARY OF THE INVENTION

In the socket for semiconductor integrated circuit of JP-A 62-110282, only the interior upper wall of the socket main body is provided with pins to be in contact with the semiconductor integrated circuit. To put it differently, pins are not provided in both of the interior upper wall and the interior bottom wall of the socket main body, but rather only in one of the above-mentioned two walls. For this reason, the socket for semiconductor integrated circuit of JP-A 62-110282 allows the analysis on only one of the front-side surface and the back-side surface of the chip. No analysis can be done if the chip is placed upside down. In addition, having no terminal for the connection to an external monitor, the socket for semiconductor integrated circuit does not allow electrical-characteristics observation in the vicinities of the pins of the semiconductor integrated circuit by use of an oscilloscope or the like.

A socket for semiconductor integrated circuit of the present invention is a socket for semiconductor integrated circuit on which a semiconductor integrated circuit is mounted. The socket includes: a socket main body which covers both a front-side surface and a back-side surface of a semiconductor integrated circuit and includes a window formed above any one of the front-side surface and the back-side surface of the semiconductor integrated circuit; first terminals which are provided corresponding respectively to external terminals of the semiconductor integrated circuit; second terminals which are provided corresponding respectively to the external terminals of the semiconductor integrated circuit at the time when the semiconductor integrated circuit is mounted upside down; and wirings which electrically connect the first terminals to the corresponding second terminals, respectively. Accordingly, an analysis on both the front-side surface and the back-side surface of the semiconductor integrated circuit can be conducted without exchanging the socket for semiconductor integrated circuit. This makes the analysis on semiconductor integrated circuit easier.

The invention makes it possible to provide a socket for semiconductor integrated circuit that enables easy analysis of a semiconductor integrated circuit.

### BRIEF DESCRIPTION OF THE DRAWINGS

FIG. 1 is a sectional diagram illustrating the configuration of an LSI socket according to an embodiment, on which a package is mounted.

FIG. 2 is a sectional diagram illustrating the configuration of the LSI socket according to the embodiment, on which the package is mounted upside down.

FIG. 3 is a sectional diagram illustrating the LSI socket according to the embodiment in a state where the package is analyzed by a different measuring apparatus.

### DESCRIPTION OF THE PREFERRED EMBODIMENTS

### Embodiment

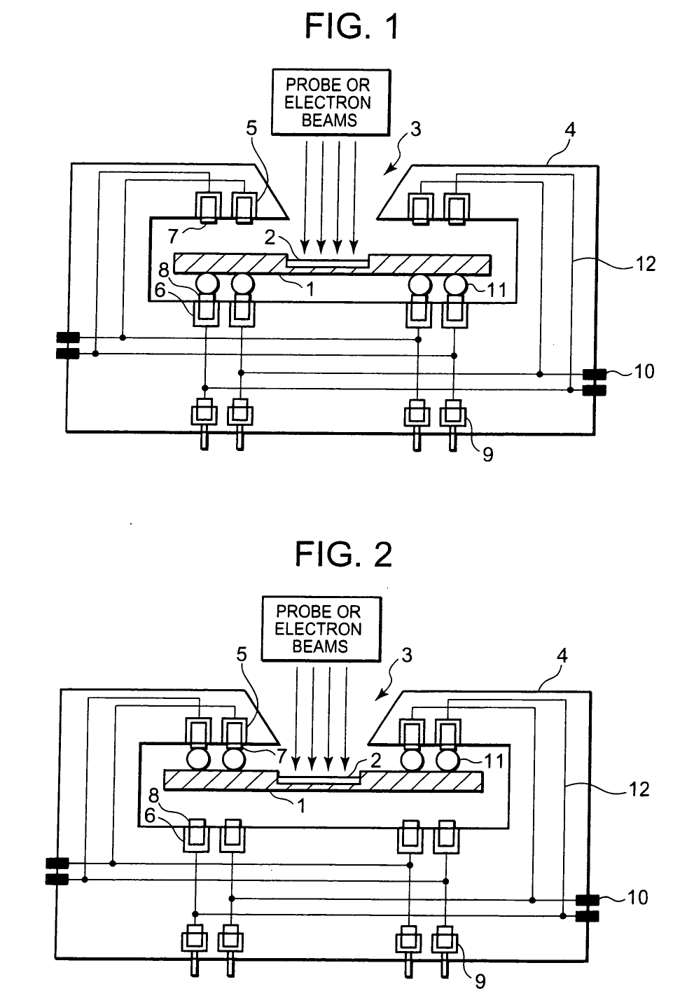

A socket for semiconductor integrated circuit according to an embodiment of the invention will be described below. A socket for semiconductor integrated circuit is an apparatus used to conduct an electrical test on a semiconductor integrated circuit such as a bare chip and a packaged chip. The term “chip” refers to an integrated circuit (IC) of, for example, large scale integration (LSI). In the following description, a term “LSI socket” is used to represent a socket for semiconductor integrated circuit. FIG. 1 is a sectional diagram illustrating the configuration of an LSI socket on which a package is mounted.

The LSI socket includes a socket main body 4 which covers both the front-side surface and the back-side surface of a package 1 mounted thereon, and which includes a window 3 formed above either one of the front-side surface and the back-side surface of the package 1. Specifically the socket main body 4 is formed in a frame shape, and has a hollow space for mounting the package 1 therein. The socket main body 4 of this embodiment covers almost all the surfaces of the package 1 except for the portion corresponding to the window 3. In other words, the package 1 is exposed outside only at the portion corresponding to the window 3.

The window 3 passes through the socket main body 4 from the inner side to the outer side. The window 3 of this embodiment is formed at the center in the upper portion of the socket main body 4. To put it differently, the window 3 of this embodiment is formed above the front-side surface of the package 1. To be more precise, the window 3 is formed above the front-side surface of a chip 2 in the package 1. The window 3 enables the probes to be directly brought into contact with the surface of the chip 2 from above the LSI socket, and also enables the electron beams to be observed. The window 3 becomes gradually wider from a package 1 side to an outer side. More specifically, the window 3 is an opening that becomes gradually wider from the inner side to the outer side of the socket main body 4. Such a shape of the window 3 makes it easier to observe the chip 2 located in the hollow space of the socket main body 4. In addition, the dimensions of the window 3 are equal to or larger than the planar dimensions of the chip 2. For example, the dimensions of the window 3 on the inner side of the socket main body 4 are substantially equal to the planar dimensions of the chip 2.

The socket main body 4 includes as first terminals bottom-side socket pins 8 that are formed corresponding respectively to external terminals (package balls 11) of the package 1. Specifically, the bottom-side socket pins 8 are provided in the same number as the package balls 11, and are disposed at positions corresponding respectively to the package balls 11. In this embodiment, the plural bottom-side socket pins 8 are arranged in the interior bottom wall of the socket main body 4. Specifically, in FIG. 1, four bottom-side socket pins 8 are arranged. The plural bottom-side socket pins 8 are inserted respectively into plural bottom-side pin-insertion holes 6 formed in the interior bottom wall of the socket main body 4.

The socket main body 4 also includes as second terminals upper-side socket pins 7 that are formed corresponding respectively to the package balls 11 of the package 1 at the time when the package 1 is mounted upside down. Specifically, the upper-side socket pins 7 are provided in the same number as the bottom-side socket pins 8, and are disposed at the substantially same positions as the bottom-side socket pins 8 when viewed from above. The plural upper-side socket pins 7 are arranged in the interior upper wall of the socket main body 4. Specifically, in FIG. 1, four of the upper-side socket pins 7 are arranged in total in such a manner that two of the upper-side socket pins 7 are provided at either side of the window 3. The plural upper-side socket pins 7 are inserted respectively into plural upper-side pin-insertion holes 5 formed in the interior upper wall of the socket main body 4.

Socket pins 9 for test board are provided in the back-side surface of the socket main body 4. The socket pins 9 for test board are connected to a test-board substrate that is placed on a semiconductor testing apparatus (IC tester). The socket pins 9 for test board are provided in the same number as the upper-side socket pins 7 and as the bottom-side socket pins 8, and are disposed at the substantially same positions as the upper-side socket pins 7 and as the bottom-side socket pins 8 when viewed from above.

Pins 10 for external monitor are provided in external surfaces of the socket main body 4. The pins 10 for external monitor are connected to connecting portions of another measuring apparatus. The number of the pins 10 for external monitor is the same as that of the upper-side socket pins 7, as that of the bottom-side socket pins 8, and that of the socket pins 9 for test board. In FIG. 1, four of the pins 10 for external monitor are provided in total in such a manner that two of the pins 10 for external monitor are arranged in each of opposed sidewalls of the socket main body 4.

Inside the socket main body 4, wirings 12 are each provided to electrically connect corresponding ones of the upper-side socket pins 7, the bottom-side socket pins 8, the socket pins 9 for test board, and the pins 10 for external monitor to one another. The wirings 12 connect the upper-side socket pins 7 to the respective bottom-side socket pins 8 according to the arrangement of the package balls 11. Specifically, each pair of the upper-side socket pin 7 and the bottom-side socket pin 8 that are connected to the same package ball 11 are electrically connected to each other by one of the wirings 12. In this embodiment, one of the wirings 12 connects each pair of the upper-side socket pin 7 and the bottom-side socket pin 8 which are positioned symmetrically in the right-and-left direction when viewed from above. For example, in FIG. 1, the rightmost upper-side socket pin 7 is electrically connected to the leftmost bottom-side socket pin 8 by one of the wirings 12. The LSI socket has a configuration that has been described thus far.

The package 1 including the chip 2 is mounted on the LSI socket as described above. For example, a ball grid array (BGA) type package may be used as the package 1. A BGA-type package has package balls 11 arranged in a grid pattern on the back-side surface of the package 1. The upper side of the package 1 is not shielded, so that the front-side surface of the chip 2 in the package 1 is exposed outside.

The package 1 is placed in the socket main body 4 with the package balls 11 directed towards the interior bottom wall. The package balls 11 are thus connected respectively to the bottom-side socket pins 8. Then, the socket pins 9 for test board are connected to a test-board substrate that is to be mounted on an IC tester. The package 1 and the IC tester are thus electrically connected to each other by the test-board substrate. As a result, the operation state of the chip 2 is ready to be observed by use of the IC tester while the probes are brought into contact with the front-side surface of the chip 2 through the window 3, or the failure analysis is ready to be conducted using electron beams through the window 3.

Incidentally, along with the recent development of multilayer LSI metal wirings, the analysis on the chip 2 from the upper surface becomes more difficult and the analysis from the back-side surface becomes more common. The description given by referring to FIG. 1 is based on an exemplar case where the chip 2 is analyzed from the front-side surface of the chip 2. The LSI socket of the present embodiment also allows the analysis from the back-side surface of the chip 2. FIG. 2 is a sectional diagram illustrating the configuration of the LSI socket with the package 1 mounted upside down. Note that the configuration of the LSI socket is the same as that of the LSI socket shown in FIG. 1.

FIG. 2 shows that the lower side (the side where the package balls 11 are provided) of the package 1 is not shielded, so that the back-side surface of the chip 2 in the package 1 is exposed outside. The package 1 is placed in the socket main body 4 with the package balls 11 directed towards the interior upper wall. The package balls 11 are thus connected respectively to the upper-side socket pins 7. Then, the socket pins 9 for test board are connected to a test-board substrate that is to be mounted on an IC tester. The package 1 and the IC tester are thus electrically connected to each other by the test-board substrate. As a result, the operation state of the chip 2 is ready to be observed by use of the IC tester while the probes are brought into contact with the front-side surface of the chip 2 through the window 3, or the failure analysis is ready to be conducted using electron beams through the window 3.

As has been described thus far, the LSI socket of this embodiment includes: the bottom-side socket pins 8 provided corresponding respectively to the package balls 11; and the upper-side socket pins 7 provided corresponding respectively to the package balls 11 at the time when the package 1 is mounted upside down on the LSI socket. The upper-side socket pins 7 are electrically connected to the respective bottom-side socket pins 8 with the corresponding wirings 12. Accordingly, both of the front-side surface and the back-side surfaces of the chip 2 can be analyzed without exchange of the LSI socket. To put it differently, analyzing the two surfaces of the chip 2 does not require fabrication of two different kinds of LSI sockets. Accordingly, a semiconductor integrated circuit such as the chip 2 can be analyzed easily. In addition, cost reduction for the analysis can be accomplished.

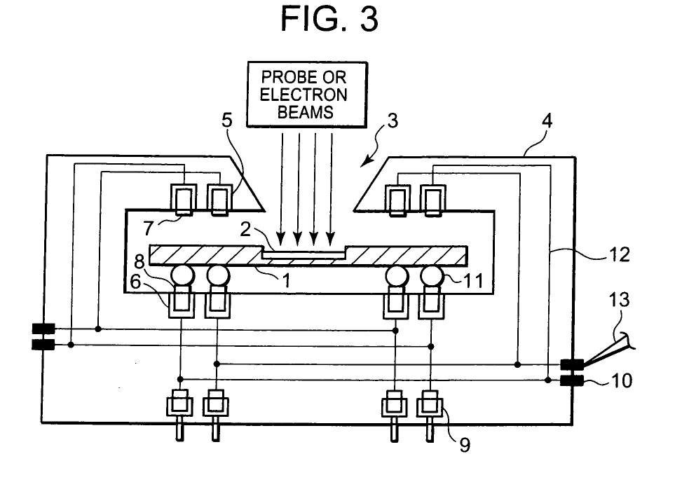

In each of the examples shown in FIGS. 1 and 2, the electrical characteristics of the chip 2 are analyzed by use of the test-board substrate, but may be also analyzed by connecting the LSI socket directly to another measuring apparatus such as an oscilloscope. FIG. 3 is a sectional diagram illustrating the LSI socket in a state where the chip 2 is analyzed using a different measuring apparatus. Note that the configuration of the LSI socket shown in FIG. 3 is the same as that of the LSI socket shown in FIG. 1. In addition, as in the case of FIG. 1, the package 1 is mounted with the front-side surface of the chip 2 directed towards the window 3.

FIG. 3 shows that one of the pins 10 for external monitor is connected to a connecting portion 13 of the different measuring apparatus. To put it differently, the pin 10 for external monitor is connected directly to the connecting portion 13 of the different measuring apparatus without the test-board substrate or the like interposed as described above. In addition, the wirings. 12 that connect the upper-side socket pins 7 to the respective bottom-side socket pins 8 are also connected to the corresponding pins 10 for external monitor. Specifically, each of the pins 10 for external monitor is electrically connected to the corresponding ones of the upper-side socket pins 7 and the bottom-side socket pins 8. Accordingly, the different measuring apparatus is electrically connected to the package ball 11. In this way, the electrical characteristics can be analyzed for each of the package balls 11 by the different measuring apparatus. The direct connection with the different measuring apparatus as described above allows the electrical characteristics to be analyzed without receiving the influence exerted by the test-board substrate. Consequently, the electrical characteristics can be analyzed correctly.

As has been described thus far, the LSI socket of this embodiment makes it possible to observe the electrical characteristics of the portions near the package balls 11. In addition, when the package 1 is mounted upside down on the LSI socket as shown in FIG. 2, the electrical characteristics can be analyzed similarly. Accordingly, a semiconductor integrated circuit can be analyzed easily.

Note that a BGA-type package is used as the package 1 in this embodiment. The BGA-type package, however, is not the only possible example of package 1. In addition, socket pins of this embodiment are provided in the interior upper wall and the interior bottom wall of the socket main body 4 corresponding to the package balls 11 of the BGA-type package. The socket pins, however, may be provided in locations other than those. The locations of the socket pins may vary depending both upon the locations of the external terminals of the semiconductor integrated circuit to be mounted on the socket main body 4 and upon the locations of the external terminals of the semiconductor integrated circuit to be mounted upside down on the socket main body 4. For example, socket pins may be provided in interior side walls of the socket main body 4 when appropriate.

The foregoing description clearly shows the usefulness of the invention in testing the electrical characteristics of a semiconductor device. Nevertheless, the foregoing description is no more than a description of an embodiment of the invention, and is not the only possible implementation form of the invention. In addition, some of the elements of the foregoing embodiment maybe combined together to implement the invention. Moreover, various modifications and alterations may be made within the gist of the invention.

What is claimed is:

1. A socket for semiconductor integrated circuit on which a semiconductor integrated circuit is mounted, the socket comprising:
a socket main body which covers both a front-side surface and a back-side surface of the semiconductor integrated circuit and which includes a window formed above any one of the front-side surface and the back-side surface of the semiconductor integrated circuit;
first terminals which are provided corresponding respectively to external terminals of the semiconductor integrated circuit;
second terminals which are provided corresponding respectively to the external terminals of the semiconductor integrated circuit at the time when the semiconductor integrated circuit is mounted upside down; and
wirings which electrically connect the first terminals to the corresponding second terminals, respectively.

2. The socket for semiconductor integrated circuit according to claim 1, further comprising terminals for external monitor which are provided on an external surface of the socket main body and which are to be connected to a measuring apparatus,
wherein the wirings electrically connect the terminals for external monitor both to the corresponding first terminals and to the corresponding second terminals, respectively.

3. The socket for semiconductor integrated circuit according to claim 1, wherein the window becomes gradually wider toward an outer side from a side that is closer to the semiconductor integrated circuit than the outer side.

4. The socket for semiconductor integrated circuit according to claim 2, wherein the window becomes gradually wider toward an outer side from a side that is closer to the semiconductor integrated circuit than the outer side.
